(19) United States
(12) Patent Application Publication
(10) Pub. No.: US 2004/0166602 A1
(43) Pub. Date: Aug. 26, 2004

(54) Electro-thermally actuated lateral-contact microrelay and associated manufacturing process

(76) Inventors: Ye Wang, San Francisco, CA (US); Norman C. Tien, Davis, CA (US)

Correspondence Address: PARK, VAUGHAN & FLEMING LLP, 508 SECOND STREET, SUITE 201, DAVIS, CA, 95616, US

(21) Appl. No.: 10/758,877

(22) Filed: Jan. 16, 2004

Related U.S. Application Data
(60) Provisional application No. 60/441,074, filed on Jan. 17, 2003.

(51) Int. Cl. H01L 21/00; H01L 29/82

(52) U.S. Cl. 438/50; 438/53; 257/415; 257/419

(57) ABSTRACT

One embodiment of the present invention relates to a lateral-contact microrelay with an electro-thermal actuator. This microrelay includes a contact head configured to make an electrical connection between a first signal line and a second signal line. It also includes an electro-thermal actuator, which is coupled to the contact head and is configured to laterally displace the contact head so that the closing action of the contact head is parallel to the plane of the semiconductor wafer upon which the microrelay is fabricated. In a variation on this embodiment, the electro-thermal actuator comprises a substantially V-shaped beam, wherein thermal expansion caused by current flowing through the substantially V-shaped beam actuates the contact head to make the electrical connection between the first signal line and the second signal line.

### RELATED APPLICATION

This application hereby claims priority under 35 U.S.C. 119 to U.S. Provisional Patent Application No. 60/441,074, filed on Jan. 17, 2003, entitled, “Low-Voltage Lateral-Contact Microrelays for RF Applications,” by inventors Ye Wang and Norman C. Tien (Attorney Docket No. UC03-272-1PSP).

### BACKGROUND

1. Field of the Invention

The present invention relates to microrelays. More specifically, the present invention relates to the design and associated manufacturing process for a microrelay that is electro-thermally actuated, and which has a lateral closing action that is parallel to the plane of a semiconductor wafer upon which the microrelay is fabricated.

2. Related Art

Recent advances in MicroElectroMechanical System (MEMS) technology have led to the development of new types of MEMS devices. In particular, MEMS switches are one of the most promising micromachined products, and these switches have recently become the focus of a significant amount of development effort.

MEMS switches have many potential applications, including signal routing in RF system front-ends, impedance matching networks, filter-path selection circuits and other high-frequency reconfigurable circuit applications. Compared to their conventional electromechanical or solid-state counterparts, micromachined switches offer many advantages in terms of low insertion loss, high off-state isolation and linearity, high breakdown voltage and integration capability.

The majority of MEMS switches operate through a vertical closing action. Because semiconductor layers are very thin, gap distances for these types of vertical relays are consequently small. These small gap distances give rise to problems in achieving sufficient electrical isolation for the switches to be useful in many applications. Furthermore, the majority of existing MEMS switch designs employ electrostatic actuation mechanisms, which typically require large actuation voltages.

Additionally, most conventional parallel-plate MEMS switches have limited RF performance due to loss caused by capacitive coupling between the contacting bar and the substrate at high frequencies. Note that an adequate closing gap to achieve high isolation typically requires a large actuation voltage. Furthermore, the signal lines and the contacting bar typically have to be fabricated in two separate process steps.

Some researchers are investigating lateral contact microrelays with a closing action that is parallel to the plane of the semiconductor chip. (see E. J. J. Kruglick and K. S. J. Pister, “Lateral MEMS Microcontact Considerations,” IEEE J. Microelectromechanical Systems, vol. 8, no. 3, pp. 264-271, September 1999). These lateral-contact microrelays have the advantage that the gap distance can be defined lithographically. This enables the gap distance to be made sufficiently large to provide adequate isolation for high-standoff voltages. However, existing lateral-contact designs generally require non-standard post-processing steps and are only suitable for DC applications.

Hence, what is needed is a microrelay that operates without the large actuation voltages required by electrostatic actuation, and without the electrical isolation problems associated with relays that have a vertical closing action.

### SUMMARY

One embodiment of the present invention relates to a lateral-contact microrelay with an electro-thermal actuator. This microrelay includes a contact head configured to make an electrical connection between a first signal line and a second signal line. It also includes an electro-thermal actuator, which is coupled to the contact head and is configured to laterally displace the contact head so that the closing action of the contact head is parallel to the plane of the semiconductor wafer upon which the microrelay is fabricated.

In a variation on this embodiment, the electro-thermal actuator comprises a substantially V-shaped beam, wherein thermal expansion caused by current flowing through the substantially V-shaped beam actuates the contact head to make the electrical connection between the first signal line and the second signal line.

In another variation on this embodiment, the electro-thermal actuator comprises a substantially V-shaped central beam cascaded between two substantially V-shaped side beams, wherein the substantially V-shaped side beams act to increase the displacement of the substantially V-shaped central beam during actuation.

In a variation on this embodiment, the electro-thermal actuator can be comprised of, silicon, polysilicon, nickel, or tungsten.

In a variation on this embodiment, the contact head and associated portions of the first and second signal lines are covered with a layer of sputtered gold.

In a variation on this embodiment, the contact head is coupled to the electro-thermal actuator through an insulator. In a further variation, the insulator can be comprised of, silicon nitride or silicon dioxide.

In a variation on this embodiment, the electro-thermal actuator has a driving voltage in the range of a few Volts.

In a variation on this embodiment, the shape of the contact head can be, square, angled, or rounded.

In a variation on this embodiment, the microrelay is an element in an array of microrelays.

In a variation on this embodiment, the microrelay is fabricated using a process that involves: (1) depositing a first low-stress silicon nitride layer as an isolation layer on a semiconductor wafer; (2) depositing and patterning a sacrificial silicon dioxide layer; (3) depositing and patterning a second low-stress silicon nitride layer to produce an insulator that couples the contact head with the electro-thermal actuator; (4) depositing and patterning a polysilicon layer to produce both the contact head and the electro-thermal actuator; (5) performing a partial release operation to ensure separation of sputtered gold on the contact head and sputtered gold on the first and second signal lines, and also to ensure removal of unwanted gold in the region between the contact head and the first and second signal lines; (6) sputtering and lifting off the layer of sputtered gold; and (7) performing a full release operation.

### BRIEF DESCRIPTION OF THE FIGURE

FIG. 1 illustrates a microrelay in accordance with an embodiment of the present invention.

FIG. 2 illustrates cascaded thermal actuator beams in accordance with another embodiment of the present invention.

FIG. 3A illustrates deposition of a low-stress SiN isolation layer in accordance with an embodiment of the present invention.

FIG. 3B illustrates deposition and patterning of a sacrificial SiO₂ layer and a low-stress SiN connection in accordance with an embodiment of the present invention.

FIG. 3C illustrates deposition and patterning of a polysilicon layer and a partial release in accordance with an embodiment of the present invention.

FIG. 3D illustrates sputtering a lift off of gold and an HF release in accordance with an embodiment of the present invention.

FIG. 4A illustrates a first design for an SiN insulator that couples the contact head with the electro-thermal actuator in accordance with an embodiment of the present invention.

FIG. 4B illustrates a second design for an SiN insulator in accordance with an embodiment of the present invention.

FIG. 4C illustrates a third design for an SiN insulator in accordance with an embodiment of the present invention.

FIG. 4D illustrates a fourth design for an SiN insulator in accordance with an embodiment of the present invention.

FIG. 5 presents a flow chart illustrating the process of fabricating an electro-thermally actuated lateral-contact microrelay in accordance with an embodiment of the present invention.

Table 1 illustrates various actuator test structures and their simulated displacements in accordance with an embodiment of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

### Lateral-Contact Microrelay Design

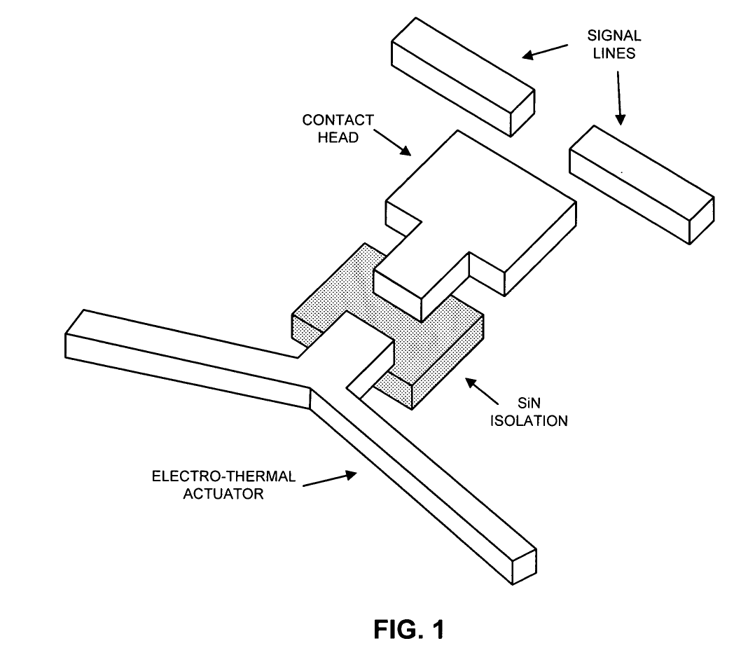

FIG. 1 illustrates the operation principle of the microrelay in accordance with an embodiment of the present invention. This microrelay utilizes electro-thermal actuators, for which extensive research has been done both theoretically and experimentally. In one embodiment of the present invention, thermal expansion caused by current flowing through a V-shaped beam actuates the contact head through a silicon nitride connection. The resulting in-plane motion of the contact head allows it to move forward and connect the RF signal lines via sidewall contact. These V-shaped actuator beams provide rectilinear displacements caused by resistive heating and provide large output forces in the range of millinewtons. This results in a stable contact with low contact resistance in the range of milliohms. In one embodiment of the present invention, the contact head and the signals lines are covered with a layer of sputtered gold (not shown in FIG. 1).

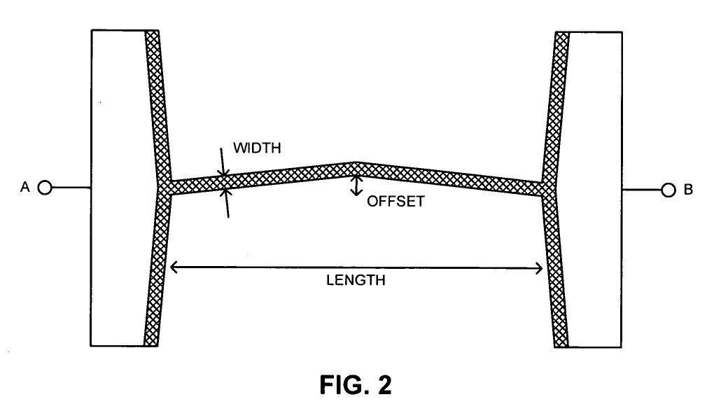

In an alternative embodiment of the present invention, actuator beams of the same dimension are cascaded to produce larger a displacement, as depicted in FIG. 2. In FIG. 2, current flowing between terminals A and B causes all three V-beams to expand due to resistive heating. Moreover, the thermal expansion of the two side beams increases the vertical displacement of the central beam. This generates a larger deflection at the tip of the central beam compared with a single actuator beam.

TABLE 1

| | Length | Width | Offset | Displacement |
|---|---|---|---|---|
| Type1 | 200 μm | 2 μm | 10 μm | 5.4 μm |
| Type2 | 240 μm | 2 μm | 10 μm | 7.2 μm |
| Type3 | 240 μm | 1 μm | 15 μm | 6.2 μm |
| Type4 | 260 μm | 1.5 μm | 10 μm | 7.9 μm |
| Type5 | 280 μm | 2 μm | 10 μm | 8.6 μm |
| Type6 | 300 μm | 2 μm | 15 μm | 9.2 μm |

In an exemplary implementation, a single actuator beam has a length of 200 μm, a width and thickness of 2 μm and a center offset of 10 μm. An actuator beam with these design parameters is calculated to have a high shock resistance>5000 g (g=9.8 m/s²) and self-resonance frequency of 31.9 kHz, which indicates good mechanical robustness. The microrelay itself occupies an area of 200×220 μm² without considering the RF testing pad.

Test structures of cascaded actuator beams with various dimensions have designed and simulated. Table 1 presents the design parameters and values from an ANSYS simulation of their displacements under a given thermal load. Note that the Type1 design provides nominal dimensions for an exemplary implementation.

In one embodiment of the present invention, gold is used as a contact metal because of its low resistivity, good stability and efficiency in RF signal propagation. It has a skin depth of 0.71 μm at 12 GHz and 0.45 μm at 30 GHz. In one embodiment of the present invention, a thickness of 0.5 μm is used due to sputtering limit. Note that sputtered gold is known to have higher hardness which results in less surface damage for metallic microcontacts.

Different contact head shapes including rounded, square and angled have been designed to explore their reliabilities. Contact head areas between 700 μm² to 1200 μm² have been designed after considering the tradeoff between contact resistance and the load the contact head puts on the extension beams. In one embodiment of the present invention, the closing gap between the contact head and the signal lines is between 3-5 μm to ensure good sidewall coverage of the sputtered gold in the trench.

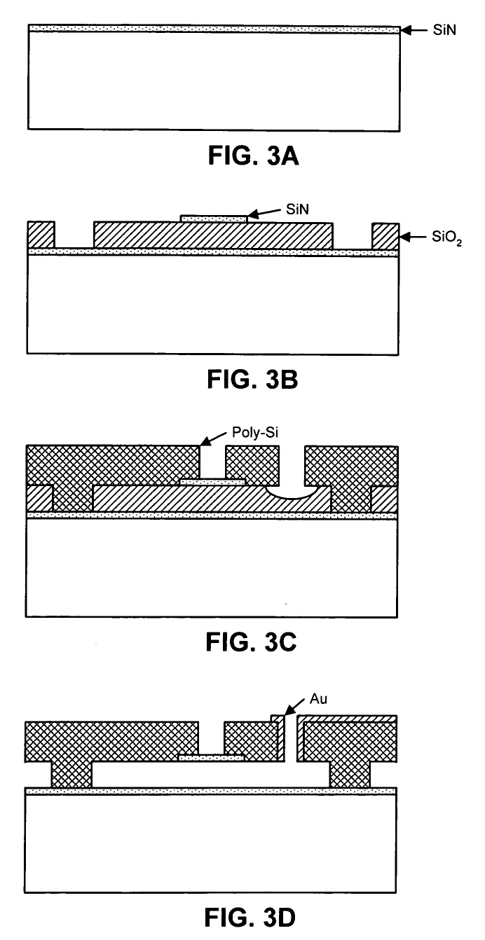

An exemplary fabrication process for the microrelay is depicted in FIGS. 3A-3D and in the flow chart illustrated in FIG. 5. First, as illustrated in FIG. 3A, 0.6 μm of Low-Pressure Chemical-Vapor-Deposited (LPCVD) low-stress silicon nitride is deposited at temperature of 850° C. It is used as an isolation layer to reduce substrate loss (step 502).

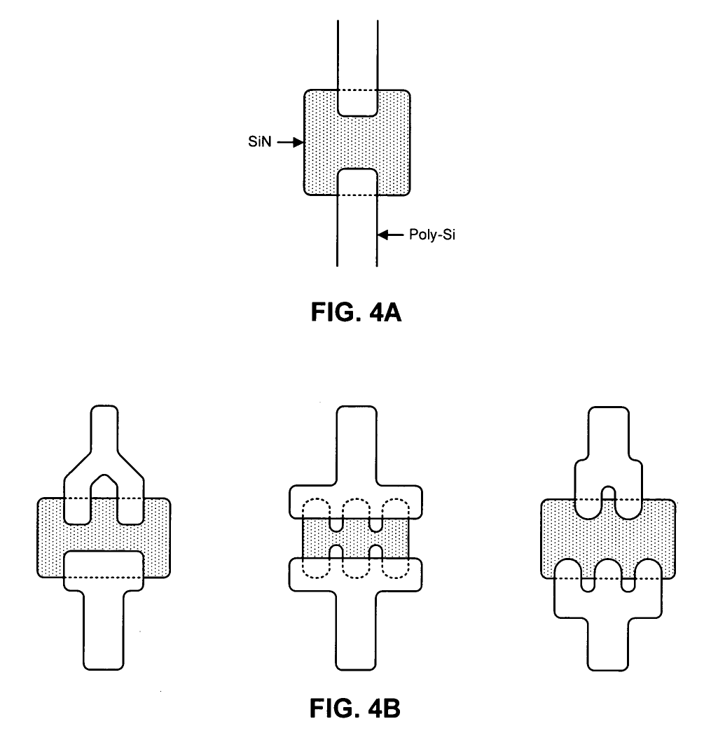

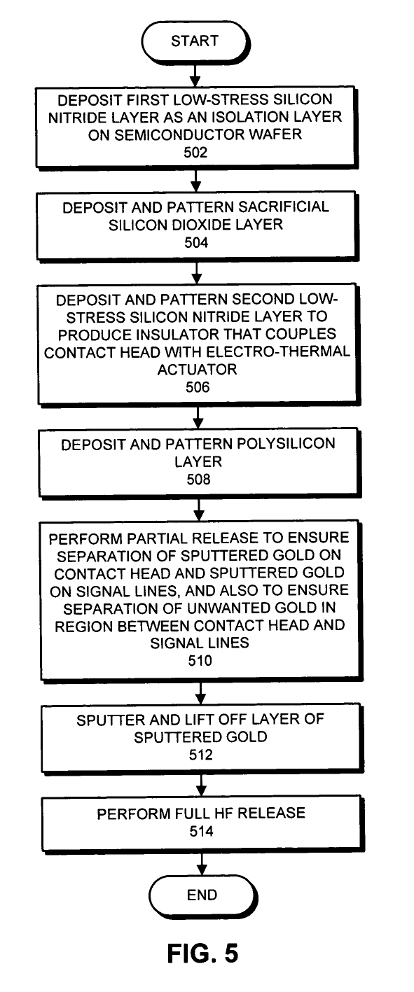

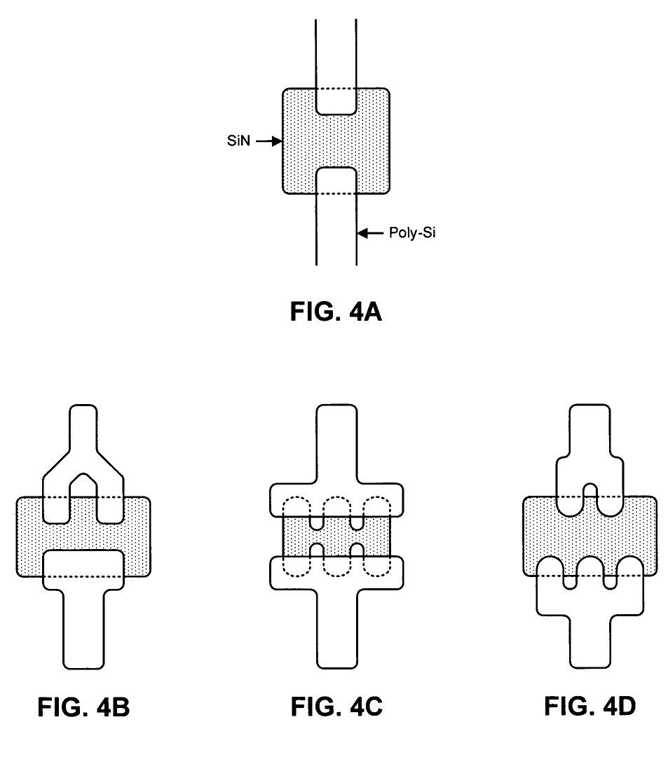

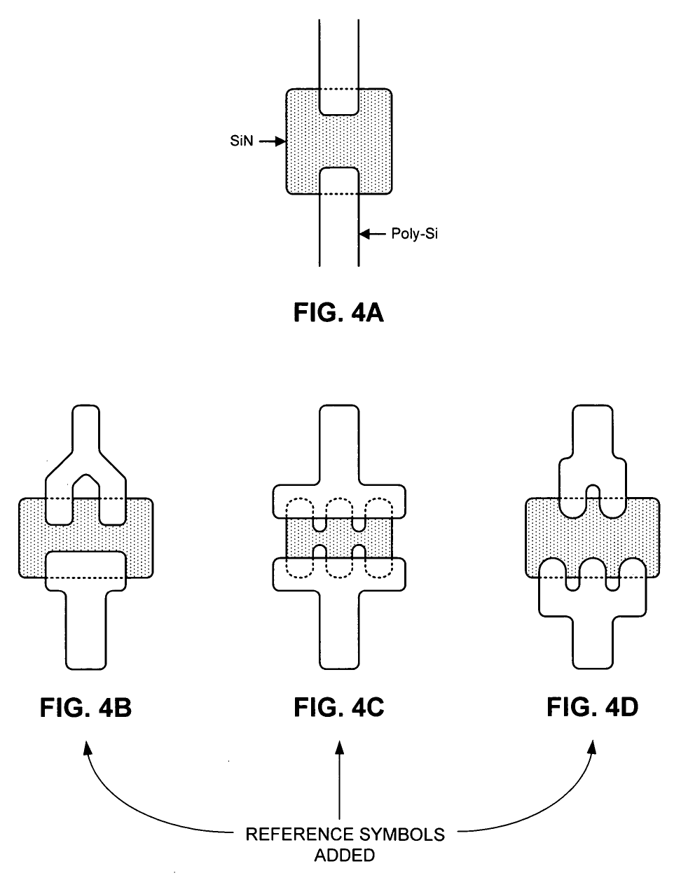

Then, as illustrated in FIG. 3B, 2 μm of sacrificial oxide is deposited and anchors are patterned (step 504). Afterwards another 0.6 μm of LPCVD low-stress silicon nitride is deposited and patterned. It serves as the structural connection as well as the electrical and thermal isolation between the actuation structure and the contact structure (step 506). FIG. 4A illustrates how a silicon nitride structure can be used to connect two polysilicon structures (such as the contact head and the actuator) in accordance with an embodiment of the present invention. A number of alternative connection structures are illustrated in FIGS. 4B-4D.

Next, as illustrated in FIG. 3C, 2 μm of in situ doped n-type polysilicon film is deposited at 620° C., and it is patterned using 0.4 μm oxide as a hard mask (step 508). A partial release step is then performed at the closing gap region to ensure the separation of sputtered gold on the contact head sidewall and the signal lines, and to ensure the removal of unwanted gold in the area between them (step 510).

Then, as illustrated in FIG. 3D, a thin layer of gold (0.3-0.5 μm) is sputtered and lifted off, leaving gold only on the contact sidewalls and signal routing lines (step 512). Finally, the device is released in hydrofluoric acid and the polysilicon and silicon nitride structures are suspended above the substrate (step 514). A supercritical CO₂ drying after HF release is helpful to reduce the surface stiction of the thin actuator beams.

Note that the above-described fabrication process can be completed using standard MEMS processes with only four masks, including lift-off, and no post-processing is required. Moreover, contact metal is realized using one-step gold sputtering. The simplicity of this process provides design flexibility, and allows possible integration of this microrelay with other passive RF MEMS components.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A microrelay, comprising:
a first signal line;
a second signal line;
a contact head configured to make an electrical connection between the first signal line and the second signal line; and
an electro-thermal actuator coupled to the contact head and configured to laterally displace the contact head so that the closing action of the contact head is parallel to the plane of a semiconductor wafer upon which the microrelay is fabricated.

2. The microrelay of claim 1,
wherein the electro-thermal actuator comprises a substantially V-shaped beam;
wherein thermal expansion caused by current flowing through the substantially V-shaped beam actuates the contact head to make the electrical connection.

3. The microrelay of claim 1, wherein the electro-thermal actuator comprises a substantially V-shaped central beam cascaded between two substantially V-shaped side beams, which increase the displacement of the substantially V-shaped central beam during actuation.

4. The microrelay of claim 1, wherein the electro-thermal actuator is comprised of:
silicon;
polysilicon;
nickel; or
tungsten.

5. The microrelay of claim 1, wherein the contact head and associated portions of the first and second signal lines are covered with a layer of sputtered gold.

6. The microrelay of claim 1, wherein the contact head is coupled to the electro-thermal actuator through an insulator.

7. The microrelay of claim 6, wherein the insulator is comprised of:
silicon nitride; or
silicon dioxide.

8. The microrelay of claim 1, wherein the electro-thermal actuator has a driving voltage in the range of a few Volts.

9. The microrelay of claim 1, wherein the shape of the contact head is:
square;
angled; or
rounded.

10. The microrelay of claim 1, wherein the microrelay is fabricated using a process that involves:
deposition of low-stress silicon nitride as isolation;
deposition and patterning of sacrificial silicon dioxide;
deposition and patterning of a low-stress silicon nitride connection;
deposition and patterning of polysilicon;
a partial release operation;
sputtering and lift-off of gold; and
a full release operation.

11. The microrelay of claim 1, wherein the microrelay is an element in an array of microrelays.

12. A microrelay, comprising:
a first signal line;
a second signal line;
a contact head configured to make an electrical connection between the first signal line and the second signal line; and
an electro-thermal actuator coupled to the contact head and configured to laterally displace the contact head so that the closing action of the contact head is parallel to the plane of a semiconductor wafer upon which the microrelay is fabricated;
wherein the electro-thermal actuator comprises a substantially V-shaped beam, wherein thermal expansion caused by current flowing through the substantially V-shaped beam actuates the contact head to make the electrical connection.

13. The microrelay of claim 12, wherein the contact head and associated portions of the first and second signal lines are covered with a layer of sputtered gold.

14. The microrelay of claim 12, wherein the contact head is coupled to the electro-thermal actuator through an insulator.

15. The microrelay of claim 12, wherein the electro-thermal actuator has a driving voltage in the range of a few Volts.

16. The microrelay of claim 12, wherein the shape of the contact head is:
square;
angled; or
rounded.

17. A process for fabricating a microrelay, comprising:
depositing a first low-stress silicon nitride layer as an isolation layer on a semiconductor wafer;
depositing and patterning a sacrificial silicon dioxide layer;
depositing and patterning a polysilicon layer; and
performing a release operation;
whereby the process produces,
a polysilicon contact head configured to make an electrical connection between a first signal line and a second signal line, and
a polysilicon electro-thermal actuator coupled to the contact head and configured to laterally displace the contact head so that the closing action of the contact head is parallel to the plane of the semiconductor wafer.

18. The process of claim 17,
wherein the electro-thermal actuator comprises a substantially V-shaped beam;
wherein thermal expansion caused by current flowing through the substantially V-shaped beam actuates the contact head to make the electrical connection.

19. The process of claim 17, wherein prior to depositing and patterning the polysilicon layer, the process further comprises depositing and patterning a second low-stress silicon nitride layer to produce a silicon nitride insulator that couples the contact head with the electro-thermal actuator.

20. The process of claim 17, wherein prior to the release operation, the process further comprises producing a layer of sputtered gold on the contact head and the first and second signal lines by:
performing a partial release operation to ensure separation of sputtered gold on the contact head and sputtered gold on the first and second signal lines, and also to ensure removal of unwanted gold in the region between the contact head and the first and second signal lines; and subsequently
sputtering and lifting off the layer of sputtered gold.
